(19) United States
(12) Patent Application Publication
(10) Pub. No.: US 2026/0300672 A1
(43) Pub. Date: Oct. 1, 2026

(54) METAL SMART CARD AND METHOD FOR MANUFACTURING A SMART CARD OF THIS KIND

(71) Applicant: IDEMIA FRANCE, Courbevoie (FR)

(72) Inventors: Agnès DUVAL, Courbevoie (FR); Philippe GAC, Courbevoie (FR); Tiphaine GROULT, Courbevoie (FR)

(73) Assignee: IDEMIA FRANCE, Courbevoie (FR)

(21) Appl. No.: 19/563,260

(22) Filed: Mar. 11, 2026

(30) Foreign Application Priority Data
Mar. 25, 2025 (FR) FR2503085

(51) Int. Cl. G06K 19/077; H10W 99/00

(52) U.S. Cl. CPC G06K 19/07722; H10W 99/00

(57) ABSTRACT

A card body comprising a metal layer exhibiting a first recess formed from a first side and a second recess formed from a second side and opening into the first recess, an electronic module received in the first recess and comprising a microcircuit and a first set of bonding pads electrically connected to the microcircuit, an electrical connection block received in the second recess and having a second set of bonding pads electrically contact-connected with the first set of bonding pads, and a radio-frequency antenna disposed outside the first recess and electrically connected to the second set of bonding pads, the first set of bonding pads and the second set of bonding pads electrically interconnecting the microcircuit and the radio-frequency antenna.

### TECHNICAL FIELD OF THE INVENTION

The invention relates to a smart card, and more particularly to a metal smart card, that is to say a smart card having a card body comprising a metal layer.

The invention also relates to a method for manufacturing a smart card of this kind.

### PRIOR ART

A smart card is used in many applications, for example as a bank card, a loyalty card or an access card. It can have different formats depending on its use. A smart card is designed to perform a variety of functions, in particular performing banking transactions, authenticating the card holder, or accessing restricted areas or secure services.

A smart card generally comprises a card body in which an electronic module is integrated. The electronic module is configured to perform functions associated with the use of the card. The card body may also contain communication means that allow data interchange with an external terminal.

The smart card, in particular its electronic module, comprises, for example, external contact pads that are accessible on the surface of the card, for making an electrical connection with contact pins of the external terminal. This mode of communication is called “contact-based”.

Some smart cards comprise a radio-frequency antenna for establishing so-called “contactless” communication, allowing them to interchange data with an external terminal without a physical connection.

These smart cards can also have the ability to establish contact-based communication using the external contact pads: these cards are then referred to as “dual” cards (or cards with a dual communication interface), these cards thus being able to establish contact-based and contactless communication.

A metal smart card is a card that has at least one metal layer forming the body of the card. The visual effect of the metal, the shiny or brushed reflections and also the weight of the metal lend this type of card the impression of quality and prestige, which is sought after by some users.

However, it has been observed that the presence of metal in the body of a smart card causes major difficulties when the card incorporates a radio-frequency antenna for establishing contactless communication. This is because the metal layer acts as an electromagnetic screen and can disturb the signals exchanged by the radio-frequency antenna with the outside, thus possibly disrupting contactless communications between a smart card and an external terminal.

Solutions were then proposed to provide a metal card that is capable of establishing effective contactless communication despite the presence of the metal layer.

For example, the document US 2020/0364532 A1 describes a metal smart card in which the metal layer exhibits, on a first side, a recess that receives the electronic module. The smart card also comprises an insulating layer disposed opposite a second side of the metal layer, which is opposite from the first side, and a relay antenna carried by the insulating layer.

In one embodiment in that document, the electronic module has a radio-frequency antenna that is electromagnetically coupled with the relay antenna of the insulating layer. The metal layer then exhibits a through hole between the first recess and the insulating layer to allow magnetic (i.e. wireless) coupling between the radio-frequency antenna of the electronic module and the relay antenna of the insulating layer.

In another embodiment in that document, the electronic module has no radio-frequency antenna and is electrically connected, by way of conductive wires, to the relay antenna by conductive wires. The metal layer again exhibits a hole between the first recess and the insulating layer, inside which the conductive wires run.

There is therefore a need to provide a metal smart card that is simple to manufacture and is capable of establishing contactless communication with an external reader.

### SUMMARY OF THE INVENTION

The present invention aims to overcome all or some of the drawbacks of the prior art mentioned above, which may lead to other advantages.

To this end, the focus of the invention, according to a first aspect, is a smart card having:
a card body comprising a metal layer, the metal layer having a first side, a second side opposite from the first side, and a thickness defined between the first side and the second side, the metal layer exhibiting a first recess formed from the first side and extending over a part of the thickness of the metal layer and a second recess formed from the second side and extending over a part of the thickness of the metal layer, the first recess opening into the second recess,
an electronic module comprising:
   a support having an internal side and an external side, which is opposite from the internal side,
   an array of external contact pads disposed on the external side of the support and configured to allow contact-based communication with an external terminal,
   a microcircuit carried by the support and electrically connected to the external contact, and
   a first set of bonding pads disposed on the internal side of the support and electrically connected to the microcircuit,
      the electronic module being received in the first recess with the array of external contact pads flush with the first side of the metal layer,
an electrical connection block comprising:
   a substrate exhibiting an internal side and an external side, which is opposite from the internal side, and
   a second set of bonding pads disposed on the internal side of the substrate,
      the electrical connection block being received in the second recess with the second set of bonding pads electrically contact-connected with the first set of bonding pads of the electronic module,
a first radio-frequency antenna disposed outside the first recess and electrically connected to the second set of bonding pads of the electrical connection block,
   the first set of bonding pads of the electronic module and the second set of bonding pads of the electrical connection block electrically interconnecting the microcircuit and the first radio-frequency antenna.

In the smart card according to the invention, the first radio-frequency antenna is remote from the electronic module. It is then possible for the first radio-frequency antenna to occupy a surface area that is greater than that of the electronic module while maintaining the metallic appearance of the first side of the metal layer.

In other words, the smart card may have an electronic module of relatively small size without constraining the size of the first radio-frequency antenna. This thus allows the smart card according to the invention to have a supreme metallic appearance while being able to establish effective contactless communication.

This is because the smaller the size of the electronic module and the larger the visible metal surface area on the first side of the metal layer, the larger the size of the first radio-frequency antenna and the more effective the contactless communication.

In addition, in the smart card according to the invention, the microcircuit and the first radio-frequency antenna are electrically connected by means of the electrical connection block, which makes an electrical connection by contact (directly or by means of an electrically conductive interface element) between the first set of bonding pads of the electronic module and the second set of bonding pads of the electrical connection block.

To put it another way, to electrically interconnect the microcircuit and the first radio-frequency antenna, it suffices to introduce the electronic module and/or the electrical connection block into their respective recesses in the metal layer until the bonding pads come into contact.

The smart card according to the invention is therefore also very simple to manufacture. It will also be noted that, owing to the physical connection between the first radio-frequency antenna and the microcircuit, the signal exchanges are reliable and the energy losses are very low, further improving contactless communication performance.

The term “electrically contact-connected” is understood to mean that the second set of bonding pads makes an electrical connection with the first set of bonding pads, either by direct contact, that is to say without any intermediate element between their respective conductive surfaces, or by means of an electrically conductive interface element disposed between the two sets of pads, such as an electrically conductive adhesive.

Preferred, simple, convenient and economical features of the smart card according to the invention are presented below.

The electrical connection block may be a printed circuit board (PCB).

The electrical connection block may comprise a via, integrated in the substrate, for electrically connecting the second set of bonding pads and the first radio-frequency antenna.

A via is a metallized hole configured to make an electrical connection between two components, here the microcircuit and the first radio-frequency antenna.

The integration of a via in the electrical connection block allows simple manufacture compatible with common, well-mastered drilling and metallization techniques.

The card body may have an electrically conductive interface element disposed between the electronic module and the electrical connection block for making the electrical connection between the first set of bonding pads and the second set of bonding pads.

The electrically conductive interface element may be in the form of a paste or film. The electrically conductive interface element may be an anisotropic conductive film (ACF).

Such an interface element ensures a reliable electrical connection by compensating for surface irregularities. It thus makes it possible to reduce contact resistances.

The first radio-frequency antenna may be disposed either in the second recess in the metal layer or opposite the second side of the metal layer.

The substrate of the electrical connection block may carry the first radio-frequency antenna. The first radio-frequency antenna may be disposed in the external side of the substrate of the electrical connection block.

In this configuration, the first radio-frequency antenna is housed in a recess in the metal layer. It is therefore not necessary to add an additional layer to carry the antenna. It is then possible to assign the entire usable thickness to the metal layer, and thus maximize the weight of the card.

The maximum usable thickness corresponds to the thickness of material that can be allocated to the different layers of the card while complying with the standards that impose a maximum total thickness. This maximum total thickness is defined by standards, in particular ISO/IEC 7810, which specifies a maximum total thickness of 0.84 mm for an ID-1 format card.

The smart card may also have an insulating layer, separate from the electrical connection block, and a second radio-frequency antenna, the insulating layer carrying the second radio-frequency antenna, the insulating layer and the second radio-frequency antenna being disposed opposite the second side of the metal layer, the second radio-frequency antenna being configured to allow magnetic coupling with the first radio-frequency antenna.

In other words, the second radio-frequency antenna serves as a relay for the first radio-frequency antenna by capturing the energy of an electromagnetic field and transferring it to said first radio-frequency antenna by magnetic coupling.

Owing to its being disposed opposite the second side of the metal layer, the second radio-frequency antenna may be of a size that is larger than that of the first radio-frequency antenna. It can thus capture more energy from the electromagnetic field emitted by an external terminal than the first antenna. This improves the power of the signal received by the microcircuit.

The microcircuit may be disposed on the internal side of the support of the electronic module.

The smart card may have an external magnetic screening layer disposed between the second side of the metal layer and the insulating layer, the external magnetic screening layer exhibiting a first through opening aligned with the second recess, the electrical connection block being received at least in part in the first through opening in the external magnetic screening layer.

When an external terminal emits a magnetic field to interact with the second radio-frequency antenna, the metal layer can absorb some of the electromagnetic energy and generate eddy currents. These currents produce energy losses that reduce the intensity of the magnetic field.

The external magnetic screening layer may be made of ferrite. Ferrite has the ability to channel magnetic flux. Thus, the external magnetic screening layer, by being interposed between the metal layer and the second radio-frequency antenna, acts as a magnetic flux guide and diverts the magnetic flux from the metal layer to guide it towards the second radio-frequency antenna.

Furthermore, the configuration of the electrical connection block disposed at least in part in the first through opening in the external magnetic screening layer allows the first radio-frequency antenna to be disposed as close as possible to the second radio-frequency antenna, and thus improves the magnetic coupling.

The metal layer may comprise a first stop member configured to prevent the connection member from moving towards the first recess and/or a second stop member configured to prevent the electronic module from moving towards the second recess.

In other words, the metal layer may comprise either a first stop member or a second stop member, or both.

The presence of a first stop member and/or a second stop member facilitates the introduction of the electronic module and the electrical connection block through two opposite sides of the metal layer and guarantees correct positioning. This type of assembly allows the electronic module and the electrical connection block to be introduced simultaneously or almost simultaneously (not one after the other) and is therefore very fast.

The first stop member may be formed by the metal layer.

To put it another way, the stop member is not an add-on element. The first stop member may, for example, be machined in the metal layer. The amount of metal material removed is thus minimized, and the weight of the card is maximized.

The first stop member may be a shoulder formed by a difference in cross-section between the first recess and the second recess.

Alternatively, the first recess and the second recess may have a constant and identical cross-section.

The second stop member may be formed by the electrical connection block disposed in the second recess.

To put it another way, it is the electrical connection block in the second recess that prevents the electronic module from moving into the second recess. This configuration thus makes it possible both to facilitate the introduction of the electronic module and to electrically connect the first set of bonding pads and the second set of bonding pads.

The card may have an internal magnetic screening layer disposed in the second recess, between the electrical connection block and the first stop member.

The internal magnetic screening layer has the same function as the external magnetic screening layer vis-à-vis the first radio-frequency antenna. It may also be made of ferrite.

The internal magnetic screening layer may consist of the removed part to create the first through opening in the external magnetic screening layer. To put it another way, the part taken away to create the first through opening in the external magnetic screening layer is reused to form the internal magnetic screening layer.

The first recess may define a first perimeter on the first side of the metal layer, while the second recess may define a second perimeter on the second side of the metal layer, the first perimeter delimiting a surface area that is less than a surface area delimited by the second perimeter.

Thus, when the first radio-frequency antenna is integrated in the electrical connection block, its dimensions may be greater than those of the electronic module while maintaining the appearance of the first side of the metal layer.

The electronic module may exhibit a first contour that is lower than a second contour of the electrical connection block.

The electronic module may not have an antenna. The first contour and/or its volume may thus be relatively low.

The first perimeter may exhibit dimensions that are less than those of the second perimeter.

The second contour of the electronic connection block may exhibit dimensions that are less than or equal to those of the second perimeter, but greater than those of the first perimeter.

A play between the first contour of the electronic module (near the external contact pads or its external side) and the first perimeter may be less than or equal to 0.5 mm, that is to say between 0 mm and 0.5 mm. The play corresponds to the maximum distance measured perpendicularly between the first contour of the electronic module and the first perimeter.

The play is then so little that when looking at the first side of the smart card, the electronic module gives the impression of completely filling the first recess.

The electronic module has a volume of at least 75% of a volume of the first recess, that is to say between 75% and 100% of the volume of the first recess.

More particularly, the volume of the electronic module may be at least 80%, 85%, 90%, 95% or even 100% of the volume of the first recess.

Equally, a play between the second contour of the electrical connection block (near its external side) and the first perimeter may be less than or equal to 0.5 mm. The play corresponds to the maximum distance measured perpendicularly between the second contour of the electrical connection block and the second perimeter.

The play is then so little that when looking at the second side of the smart card, the electrical connection block gives the impression of completely filling the second recess.

The electrical connection block has a volume of at least 75% of a volume of the second recess, that is to say between 75% and 100% of the volume of the second recess.

More particularly, the volume of the electrical connection block may be at least 80%, 85%, 90%, 95% or even 100% of the volume of the second recess.

The focus of the invention is also, according to a second aspect, a method for manufacturing a smart card according to the first aspect, comprising at least steps of:
introducing the electrical connection block into the second recess from the second side of the metal layer,
introducing the electronic module into the first recess from the first side of the metal layer, the electrical interconnection between the microcircuit and the first radio-frequency antenna being produced by introducing the electronic module and/or introducing the electrical connection block into their respective recesses until the first set of bonding pads and the second set of bonding pads come into contact.

During the step of introducing the electrical connection block, the electrical connection block can be introduced until it abuts against a first stop member configured to prevent the electrical connection block from moving towards the first recess, the step of introducing the electrical connection block being able to be carried out before the step of introducing the electronic module, and, during the step of introducing the electronic module, the electronic module being able to be introduced until it abuts against the electrical connection block.

The method may also comprise a step of:
forming the first recess from the first side of the metal layer,
forming the second recess from the second side of the metal layer,
   the steps of forming the first recess and forming the second recess being carried out before the steps of introducing the electrical connection block and introducing the electronic module.

To put it another way, the electrical connection block and the electronic module are introduced only after the two recesses have been formed, thus preventing the electrical connection block or the electronic module from being damaged.

### BRIEF DESCRIPTION OF THE FIGURES

The invention, according to an exemplary embodiment, will be better understood and its advantages will become more clearly apparent on reading the detailed description that follows, which is given by way of completely non-limiting indication, with reference to the appended drawings.

FIG. 1 is a front view of a smart card according to a first embodiment according to the invention.

FIG. 2 is a sectional view, marked II-II in FIG. 1, of the smart card of FIG. 1.

FIG. 3 is a view similar to that of FIG. 2, showing a smart card according to a second embodiment.

FIG. 4 is a view similar to that of FIG. 2, showing a smart card according to a third embodiment.

FIG. 5 is a view similar to that of FIG. 2, showing a smart card according to a fourth embodiment.

FIG. 6 is a view similar to that of FIG. 2, showing a smart card according to a fifth embodiment.

FIG. 7 is a block diagram showing steps of a method for manufacturing a smart card, in accordance with the invention.

### DETAILED DESCRIPTION OF THE INVENTION

The invention is concerned with a metal smart card configured to operate in contactless mode, and also relates to the manufacture of smart cards of this kind.

In the present document, a “metal smart card” is a smart card comprising metal or a combination (alloy) of metals, in the form of a metal layer or of a plurality of metal layers.

A metal smart card can be used in many applications, for example as a bank card, an access card, an identity card, etc.

The smart card can be ISO 7816 compliant and can operate according to the EMV standard or other transaction standards, for example the NFC standard (for example according to ISO 14443-2, ISO 10373-6, EMV Contactless Certification).

A contactless smart card is, in and of itself, configured to establish contactless communication with an external reader, for example using near field communication (NFC).

To this end, a contactless smart card incorporates a radio-frequency antenna for exchanging (receiving and/or transmitting) radio-frequency signals with an external reader.

A smart card of this kind can also have the ability to establish contact-based communication using the external contact pads disposed on the surface of the card: these cards are then referred to as “dual” cards (or cards with a dual communication interface), these cards thus being able to establish contact-based and contactless communication.

There is nowadays strong demand from users for metal chip cards, in particular for the reasons mentioned above (aesthetic appearance, impression of quality, prestige, etc.).

In particular, it is desirable to produce smart cards in which a large portion of the card body is made of metal, or at least in which the card body has a metal layer with as much visible metal as possible, and also a relatively great weight.

However, when a contactless smart card has a metal layer and also a radio-frequency antenna, it has been observed that this metal layer disrupts contactless communications between the radio-frequency antenna and the external reader, in particular when the metal layer is disposed between the radio-frequency antenna and the external reader, on account of the electromagnetic screening produced by the metal layer.

Solving this problem can lead to complex smart cards with a greatly worsened metallic appearance.

The invention thus proposes overcoming this drawback by providing a “dual” metal smart card that is simple to manufacture and exhibits a robust metallic appearance.

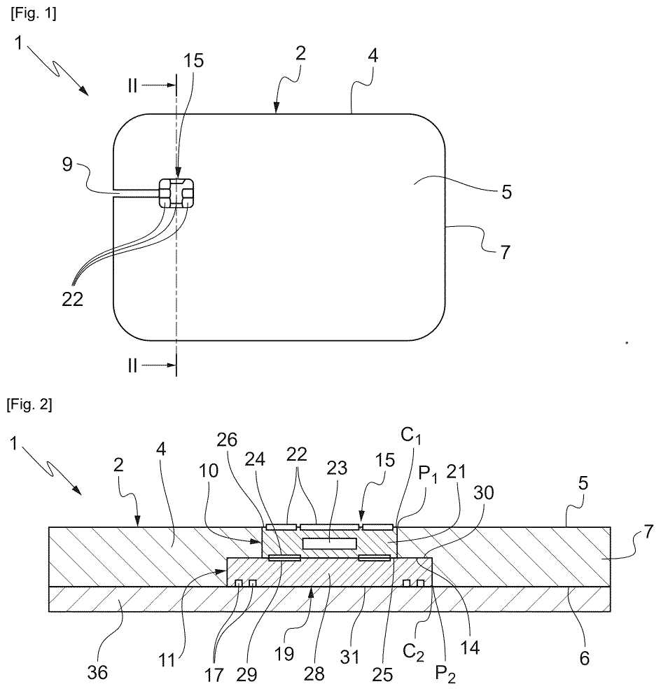

FIGS. 1 and 2 show a smart card 1 according to a first embodiment of the invention.

The smart card 1 has a card body 2 comprising a metal layer 4. This is referred to as a metal smart card.

In the example shown, the metal layer 4 is made of the same material, for example stainless steel, silver, gold, copper or tungsten. Other metals can, of course, be used.

The metal layer 4 exhibits a first side 5, a second side 6 opposite from the first side 5, and a peripheral edge 7 that joins the peripheries of the first side 5 and the second side 6 and forms an outer contour of the metal layer.

The metal layer 4 exhibits a first recess 10 formed from the first side 5 and extending over a part of the thickness of the metal layer and a second recess 11 formed from the second side 6 and extending over a part of the thickness of the metal layer.

The thickness of the metal layer 4 corresponds to the distance between its first side 5 and its second side 6, measured perpendicular to one of these sides.

The first recess 10 opens into the second recess 11. In other words, the first recess 10 communicates with the second recess 11.

In the example shown, the part of the thickness over which the first recess 10 extends is equal to approximately 50% of the thickness of the metal layer 4, and the part of the thickness over which the second recess 11 extends is also equal to about 50% of the thickness of the metal layer 4.

The first recess defines a first perimeter P1 on the first side 5 of the metal layer 4, while the second recess 11 defines a second perimeter P2 on the second side 6 of the metal layer.

The first perimeter P1 here delimits a surface area that is less than a surface area delimited by the second perimeter P2. To put it another way, the first recess 10 defines an opening on the first side 5 of the metal layer 4 that is smaller, in terms of surface area, than the opening defined by the second recess 11 on the second side 6 of the metal layer.

In the example shown, the first recess 10 and the second recess 11 have a cylindrical shape of rectangular cross-section with rounded corners, with lateral walls that extend perpendicularly to the first side 5 and/or to the second side 6 of the metal layer 4.

The cross-section of the first recess 10 is delimited by the first perimeter P1, while the cross-section of the second recess 11 is delimited by the second perimeter P2.

Thus, in the example shown, the first recess 10 has a cross-section that is less than that of the second recess 11.

The change in cross-section between the first recess 10 and the second recess here forms a shoulder 14.

In particular, the first recess 10 and the second recess 11 are aligned along the same axis so that the shoulder 14 has the shape of a frame.

The metal layer 4 comprises a slot 9 that passes through the thickness of the metal layer and connects the peripheral edge 7 with the first recess 10 and the second recess 11.

To put it another way, the first recess 10 and the second recess 11 open onto the peripheral edge 7 by way of this slot 9.

The smart card 1 also has an electronic module 15, a first radio-frequency antenna 17 and an electrical connection block 19 configured to electrically interconnect the electronic module 15 to the first radio-frequency antenna 17.

The electronic module 15 has a support 21 on which are mounted an array of external contact pads 22, a microcircuit 23 electrically connected to the array of external contact pads 22 and a first set of bonding pads 24, here comprising two first bonding pads, electrically connected to the microcircuit 23.

The microcircuit 23 is configured to establish contactless communication with the external terminal using the first radio-frequency antenna 17.

The support 21 has an internal side 25 and an external side 26, which is opposite from the internal side 25.

The array of external contact pads 22 is disposed on the external side 26 of the support 21.

The first bonding pads 24 are disposed on the internal side 25 of the support 21.

In practice, the support is composed of a plate and a resin layer (which are not shown), with the array of external contact pads disposed on a first side of the plate and the microcircuit and the first bonding pads disposed on a second side of the plate, opposite from the first side. The resin layer is disposed on the second side of the plate and encapsulates the microcircuit. The microcircuit and the resin layer project from the internal side of the support, and in particular with respect to the first bonding pads.

The array of external contact pads 22 is configured to allow contact-based communication with an external terminal.

The electrical connection block 19 comprises a substrate 28 on which is mounted a second set of bonding pads 29, here comprising two second bonding pads, electrically connected to the first radio-frequency antenna 17.

The substrate 28 has an internal side 30 and an external side 31, which is opposite from the internal side 30.

The second bonding pads 29 are disposed on the internal side 30 of the substrate 28.

In practice, the internal side of the substrate has a cavity (not shown) that is configured to receive at least part of the microcircuit and the resin layer of the electronic module. This allows the first bonding pads, which are set back from the microcircuit and the resin layer, to come into contact with the second bonding pads.

In this embodiment, the first radio-frequency antenna 17 is carried by the substrate 28 of the electrical connection block 19.

The electrical connection block 19 here is a printed circuit board and comprises vias (not shown) for electrically connecting the second bonding pads 29 to the ends of the second radio-frequency antenna 37.

The substrate 28 is, for example, formed using FR4 (“Flame Retardant 4”).

The electronic module 15 is received in the first recess 10 with the array of external contact pads 22 flush with the first side 5 of the metal layer 4 and with the first bonding pads 24 facing the second recess 11.

The electrical connection block 19 is received in the second recess 11.

The first radio-frequency antenna 17, which is carried by the substrate 28 of the electrical connection block 19, here, is disposed outside the first recess 10 of the metal layer 4.

Here, the internal side 30 of the substrate 28 of the electrical connection block 19 abuts against the shoulder 14.

The shoulder 14 is then configured to prevent the electrical connection block 19 from moving towards the first recess 10.

The second bonding pads 29 are thus turned towards the first recess 10 and come into contact with the first bonding pads 24 to electrically interconnect the microcircuit 23 and the first radio-frequency antenna 17.

The first bonding pads 24 may be in contact with the second bonding pads 29 directly or by means of an electrically conductive interface element, such as an anisotropic conductive film.

The first radio-frequency antenna 17 comprises at least one electrically conductive turn to allow exchanges of radio-frequency signals between the smart card and an external terminal.

The smart card 1 is thus configured to establish contactless communication with an external terminal by means of the first radio-frequency antenna 17 and the microcircuit 23.

It will be noted that the electronic module 15 here has no antenna, which allows it to be of relatively small size.

In the example shown, the electronic module 15 has a generally cylindrical shape of rectangular cross-section, here with rounded corners, with a length (longest side of the rectangle) of between 11 mm and 13 mm and a width (shortest side of the rectangle) of between 8 mm and 11 mm.

The electronic module 15 can thus occupy a minor part of the surface area of the first side 5 of the metal layer 4, for example less than 5%, which allows the card to have a supreme metallic appearance.

The electronic module 15 exhibits a first contour C1 that is such that a play between the first contour and the first perimeter P1, defined by the first recess 10 on the first side 5 of the metal layer 4, is less than or equal to 0.5 mm.

Thus, when looking at the first side of the metal layer 4, the electronic module 15 seems to completely fill the first recess 10.

The electronic module 15 exhibits a volume V1 that is, for example, at least 75%, that is to say between 75% and 100%, of a volume V0 of the first recess 10.

The electrical connection block 19 here exhibits a second contour C2 that is higher than the first contour C1 of the electronic module 15.

In the example shown, the electrical connection block 19 has a generally cylindrical shape of rectangular cross-section, here with rounded corners, and with a length (longest side of the rectangle) of approximately 19 mm and a width (shortest side of the rectangle) of approximately 16 mm.

Thus, by disposing the first radio-frequency antenna 17 in the substrate 28 of the electrical connection block 19 rather than in the support 21 of the electronic module 15, it is possible to establish effective contactless communication without affecting the metallic appearance of the first side 5 of the metal layer 4.

The second contour C2 of the electrical connection block 19 is such that a play between the second contour and the second perimeter P2, defined by the second recess 11 on the second side 6 of the metal layer 4, is less than or equal to 0.5 mm.

Thus, when looking at the second side 6 of the metal layer 4, the electrical connection block 19 seems to completely fill the second recess 11.

The electrical connection block 19 exhibits a volume V3 that is, for example, at least 75%, that is to say between 75% and 100%, of a volume V2 of the second recess 11.

In the example shown, the external side 31 of the substrate 28 of the electrical connection block 19 is flush with the second side 6 of the metal layer 4 when the internal side 30 of the substrate abuts against the shoulder 14.

The second side 6 of the metal layer 4 thus defines, with the external side 31 of the substrate 28 of the electrical connection block 19, a flat surface.

The smart card 1 may also have a protective layer 36 disposed on the second side 6 of the metal layer 4.

The protective layer 36 here covers the entire surface area defined by the second side 6 of the metal layer 4 and the external side 31 of the substrate 28 of the electrical connection block 19.

The protective layer 36 has, for example, a transparent part to allow the second side 6 of the metal layer 4 to be looked at through it.

The protective layer 36 may be made of plastic or composed of an ink. The protective layer 36 may carry a magnetic track.

The protective layer 36 is fixed to the metal layer 4 by means known to those skilled in the art.

The operation of the smart card 1, including the advantage of forming a slot in the metal layer, is described in greater detail in patent application EP4465204A1 filed by the applicant.

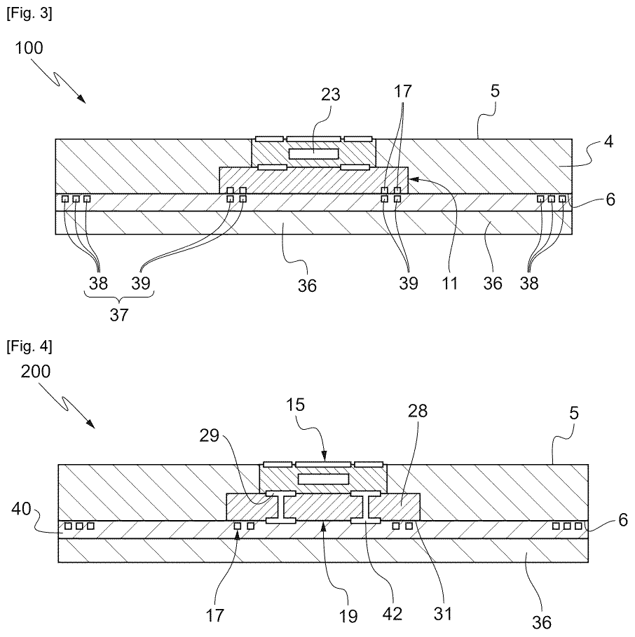

FIG. 3 shows a smart card 100 according to a second embodiment of the invention.

The smart card 100 is similar to that according to the first embodiment, except that it also has a second radio-frequency antenna 37 and an insulating layer 40 carrying the second radio-frequency antenna 37.

In the example shown, the insulating layer 40 is disposed on the second side 6 of the metal layer 4.

The microcircuit 23 is electrically connected to the first radio-frequency antenna 17, while the second radio-frequency antenna 37 is electrically insulated from the microcircuit 23 and from the first radio-frequency antenna 17.

The second radio-frequency antenna 37 is in part opposite (aligned with) the first radio-frequency antenna 17 to allow magnetic coupling with the latter, and thus to allow the microcircuit 23 to use the second radio-frequency antenna 37 to establish contactless communication with the external terminal.

The first radio-frequency antenna 17 comprises a plurality of first electrically conductive turns disposed in the second recess 11.

Here, the size of the first radio-frequency antenna 17 is limited insofar as the first conductive turns are held in the second recess 11.

The second radio-frequency antenna 37 comprises a first antenna part 38 and a second antenna part 39, which are electrically connected to one another.

The first antenna part 38 comprises second electrically conductive turns that extend opposite a part of the metal layer 4.

The second antenna part 39 comprises third electrically conductive turns that extend opposite the second recess 11 to allow coupling by magnetic induction (magnetic coupling) between the first radio-frequency antenna 17 and the second radio-frequency antenna 37.

Since the second recess 11 has no metal material, the second antenna part 39 can be magnetically coupled with the first radio-frequency antenna 17 without the metal layer 4 obstructing it.

The second antenna part 39 here is positioned opposite the first radio-frequency antenna 17, making it possible to establish effective magnetic coupling.

However, an offset may be tolerated between the first turns of the first radio-frequency antenna 17 and the third turns of the second antenna part 39 insofar as the second recess 11 nevertheless allows the magnetic coupling to be achieved.

By virtue of the magnetic coupling established between the first radio-frequency antenna 17 and the second radio-frequency antenna 37 under the effect of a magnetic field emitted, for example, by an external terminal, the microcircuit 23 can use the second radio-frequency antenna 37 to establish contactless communication with the external terminal.

The microcircuit 23 is then configured to establish contactless communication with an external terminal using the first radio-frequency antenna 17 and the second radio-frequency antenna 37 coupled together by magnetic induction.

In the example shown, the first antenna part 38 of the second radio-frequency antenna 37 occupies a larger surface area than the second antenna part 39, but especially than the first radio-frequency antenna 17, allowing more effective communication to be established than with only the first radio-frequency antenna.

The smart card 100 here has a protective layer 36 disposed on the insulating layer 40, which is interposed between the protective layer 36 and the second side 6 of the metal layer 4.

The operation of the smart card is described in greater detail in patent application EP4465204A1 filed by the applicant.

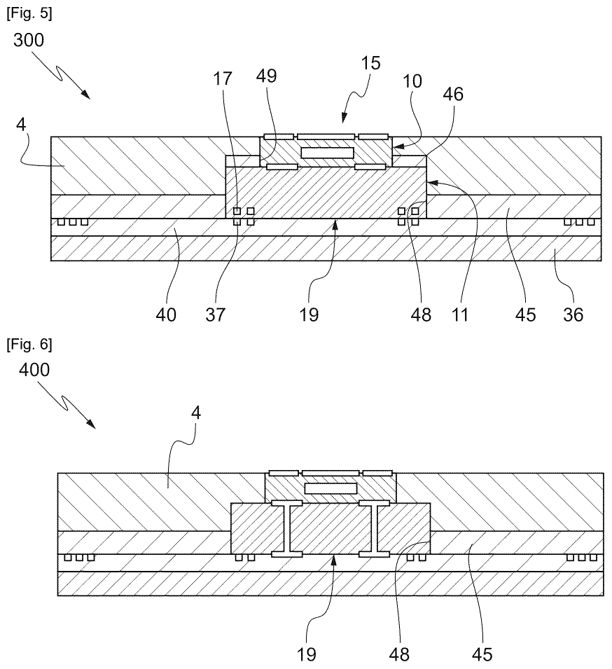

FIG. 4 shows a smart card 200 according to a third embodiment of the invention.

The smart card 200 is similar to that according to the first embodiment, except that it also has an insulating layer 40 and that the first radio-frequency antenna 17 is carried not by the electrical connection block 19, but by the insulating layer.

In other words, the first radio-frequency antenna 17 is separate from the electrical connection block 19.

The insulating layer 40 here is disposed on the second side 6 of the metal layer 4.

In the example shown, the electronic module 15 and the electrical connection block 19 have no antenna.

The electrical connection block 19 has third bonding pads 42 disposed on the external side 31 of the substrate 28.

Each third bonding pad 42 is electrically connected to a second bonding pad 29.

The connection block here comprises vias 43, integrated in the substrate 28, for electrically connecting the third bonding pads 42 to the second bonding pads 29.

Each third bonding pad 42 is electrically connected to one end of the first radio-frequency antenna 17, thus interconnecting the microcircuit 23 and the first radio-frequency antenna 17.

In the example, the first radio-frequency antenna 17 is similar to the second radio-frequency antenna of the third embodiment.

The smart card 200 here has a protective layer 36 disposed on the insulating layer 40, which is interposed between the protective layer 36 and the second side 6 of the metal layer 4.

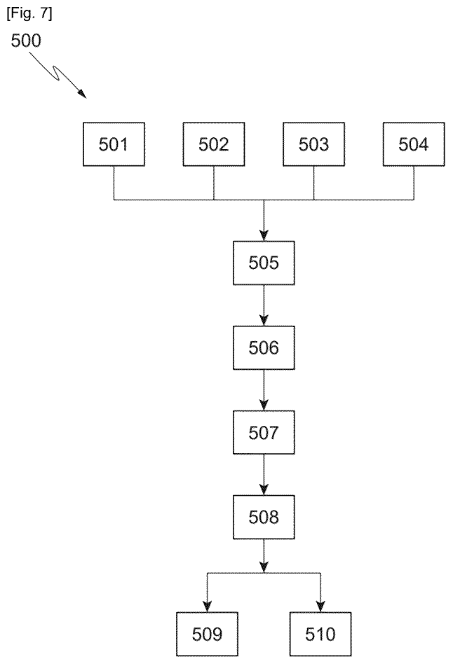

It should be noted that in this embodiment, the first radio-frequency antenna 17 may have no second antenna part 39, as shown in FIG. 6.

The operation of the smart card 200 is similar to that of the smart card according to the first embodiment.

FIG. 5 shows a smart card 300 according to a fourth embodiment of the invention.

The smart card 300 is similar to that according to the second embodiment, except that the metal layer 4 has no slot, but has magnetic screening layers 45, 46, here made of ferrite.

In particular, the smart card 300 has an external ferrite layer 45 disposed between the insulating layer 40 carrying the second radio-frequency antenna 37 and the metal layer 4, and an internal ferrite layer 46 disposed between the electrical connection block 19 and the shoulder 14.

In the example shown, the external ferrite layer 45 exhibits a first through opening 48 aligned with the second recess 11 in the metal layer 4, while the electrical connection block 19 projects from the second side 6 of the metal layer 4 and engages at least in part in the first through opening 48.

The first radio-frequency antenna 17 is towards the external side 31 of the substrate 28 of the electrical connection block 19, in the first through opening 48 in the ferrite layer.

The first radio-frequency antenna 17 is thus as close as possible to the second radio-frequency antenna 37.

The external side 31 of the substrate 28 of the electrical connection block 19 here is flush with an external side of the external ferrite layer 45, thus forming a flat surface.

The smart card 300 here has a protective layer 36 disposed on the first ferrite layer 45 and the electrical connection block 19.

In the example shown, the internal ferrite layer 46 exhibits a second through opening 49 aligned with the first recess 10 in the metal layer 4, while the electronic module 15 projects into the second recess 11 and engages at least in part in the second through opening 49.

The internal ferrite layer 46 may consist of the removed, for example cut-out, part to create the first through opening 48 in the external ferrite layer 45.

The operation of the smart card 300 is similar to that of the smart card according to the second embodiment, except that it does not allow identical communication to be established from the first side or from the second side. This is because, owing to the external ferrite layer 45, communication is more effective from the second side than from the first side of the metal layer 4.

FIG. 6 shows a smart card 400 according to a fifth embodiment of the invention.

The smart card 400 is similar to that according to the third embodiment, except that the metal layer 4 has no slot, but has a ferrite layer 45.

The ferrite layer 45 is similar to the external ferrite layer described in the fourth embodiment, as is the arrangement of the electrical connection block 19 that engages at least in part in the first through opening 48 in this layer.

It should be noted that in this embodiment, the first radio-frequency antenna 17 may have no second antenna part 39, as shown in FIG. 6.

The operation of the smart card 400 is similar to that of the smart card according to the third embodiment, except that it does not allow identical communication to be established from the first side or from the second side. This is because, owing to the external ferrite layer 45, communication is more effective from the second side than from the first side of the metal layer 4.

In the smart card 1, 100, 200, 300, 400, the first radio-frequency antenna 17 is remote from the electronic module 15. It is then possible for the first radio-frequency antenna 17 to occupy a surface area that is greater than that of the electronic module 15 while maintaining the metallic appearance of the first side 5 of the metal layer 4.

In other words, the smart card 1, 100, 200, 300, 400 may have an electronic module 15 of relatively small size without constraining the size of the first radio-frequency antenna 17. This thus allows the smart card 1, 100, 200, 300, 400 to have a supreme metallic appearance while being able to establish effective contactless communication.

This is because the smaller the size of the electronic module 15, the larger the visible metal surface area on the first side 5 of the metal layer 4, and the larger the size of the first radio-frequency antenna 17, the more efficient the contactless communication.

In addition, in the smart card 1, 100, 200, 300, 400, the microcircuit 23 and the first radio-frequency antenna 17 are electrically connected by means of the electrical connection block 19, which makes an electrical connection by bringing into contact (directly or by means of an electrically conductive interface element) the first bonding pad 24 of the electronic module 15 and the second bonding pad 29 of the electrical connection block 19.

To put it another way, in order to electrically interconnect the microcircuit 23 and the first radio-frequency antenna 17, it suffices to introduce the electronic module 15 and/or the electrical connection block 19 into their respective recesses 10, 11 in the metal layer 4 until the bonding pads 24, 29 come into contact.

The smart card 1, 100, 200, 300, 400 is therefore also very simple to manufacture. It will also be noted that, owing to the physical connection between the first radio-frequency antenna 17 and the microcircuit 23, the signal exchanges are reliable and the energy losses are very low, further improving contactless communication performance.

A description will now be given, with reference to FIG. 7, of a method 500 for manufacturing a smart card, such as that according to one of the embodiments described with reference to FIGS. 1 to 6.

The manufacturing method comprises steps of:
providing 501 a solid metal layer, that is to say one having no recesses,
providing 502 the electronic module,
providing 503 the electrical connection block, and
providing 504 a first radio-frequency antenna.

The manufacturing method also comprises a step of forming 505 a first recess from the first side of the metal layer and a step of forming 506 the second recess from the second side of the metal layer. These steps can be carried out simultaneously.

Once the first recess and the second recess have been formed, a metal layer having two communicating recesses, as described above, is obtained.

The method comprises a step of introducing 507 the electrical connection block into the second recess from the second side of the metal layer.

For a smart card according to the fourth embodiment, illustrated in FIG. 5, the manufacturing method comprises, prior to the step of introducing 507 the connection block, a step of introducing the internal magnetic screening layer into the second recess from the second side of the metal layer until it abuts against the shoulder.

When the metal layer has a shoulder, as described above, the connection block (or the internal magnetic screening layer, if applicable) is introduced until it abuts against the shoulder.

The method then comprises a step of assembling 508 the protective layer.

For a smart card according to the first embodiment, illustrated in FIG. 2, the protective layer is assembled on the second side of the metal layer using an adhesive, to form a stack.

For a smart card according to the second and third embodiments, illustrated in FIGS. 3 and 4, respectively, the manufacturing method also comprises a step of assembling the insulating layer on the second side of the metal layer using an adhesive. The protective layer is therefore assembled 508 on the insulating layer, so that the insulating layer is interposed between the metal layer and the protective layer.

For a smart card according to the fourth and fifth embodiments, illustrated in FIGS. 5 and 6, respectively, the manufacturing method comprises a step of assembling the external magnetic screening layer on the second side of the metal layer using an adhesive, a step of assembling the insulating layer on the external magnetic screening layer using an adhesive, and a step of assembling the protective layer on the insulating layer using an adhesive, so that the external magnetic screening layer is interposed between the metal layer and the insulating layer, and the insulating layer is interposed between the external magnetic screening layer and the protective layer.

It will be noted that, for the smart card according to the third and fifth embodiments, the insulating layer is assembled in such a way that the third bonding pads are electrically connected to the ends of the first radio-frequency antenna, for example by means of an electrically conductive adhesive.

The manufacturing method also comprises a step of rolling 509 the stack.

To improve the flatness of the smart card following rolling, it is possible to position a temporary insert in the first recess. This temporary insert is then removed after rolling.

The manufacturing method also comprises a step of forming 510 a cavity in the first side of the substrate of the electrical connection block from the first recess, the cavity being configured to receive at least part of the electronic module. As indicated above, in some cases, the microcircuit is disposed in such a way as to project from the internal side of the support and is encapsulated in a resin layer that also projects from the internal side of the support. The cavity may be formed by milling.

In some cases, the second bonding pads are integrated in the substrate of the connection block and are not directly accessible from its internal side. The manufacturing method then comprises a step of machining the internal side of the substrate of the electrical connection block to expose the second bonding pads.

The method then comprises a step of introducing 511 the electronic module into the first recess from the first side of the metal layer until it abuts against the electrical connection block (or against an electrically conductive film, which may be deformed).

Variants that are not illustrated are presented below.

The metal layer may consist of one or more metal materials.

If the metal layer consists of multiple metal materials, a contour of this layer may be made of a first metal material, for example stainless steel, while a part internal to the contour may be made of a second metal material, for example tungsten.

The first recess may extend over more than 50% of the thickness of the metal layer, for example over 60%, 70%, 80% or even 90%, and the second recess may extend over less than 50% of the metal thickness, for example over 40%, 30%, 20% or even 10%, and vice versa.

The first perimeter may delimit a surface area that is greater than or equal to a surface area delimited by the second perimeter.

The first recess and the second recess may have a different shape than a cylindrical shape.

The first recess and the second recess may have a cylindrical shape, but with a different, for example circular, cross-section.

The first recess may have a cross-section that is greater than or equal to that of the second recess.

The metal layer may have no stop member, in particular no shoulder.

The microcircuit may be disposed differently on the support of the electronic module, and for example may be integrated in said support, between the internal side and the external side.

The first radio-frequency antenna may be disposed on the external side of the substrate. Alternatively, it may be disposed on the internal side or on both sides at the same time (for example by comprising one or more turns on each side, connected by a via), as long as it is electrically insulated from the metal layer.

The electrical connection block may exhibit a single second bonding pad or more than two second bonding pads. The same applies to the third bonding pads.

The smart card may have no ferrite layer and the metal layer may have no slot.

The smart card may have no protective layer.

The first antenna part may have a single second conductive turn. The same applies to the second antenna part.

As regards the manufacturing method, the first recess may be formed from the second side of the metal layer, after the second recess has been formed, that is to say from the second recess.

More generally, the invention is not limited to the examples described and shown.

1. A smart card, comprising:
a card body having a metal layer, the metal layer having a first side, a second side opposite from the first side, and a thickness defined between the first side and the second side, the metal layer exhibiting a first recess formed from the first side and extending over a part of the thickness of the metal layer and a second recess formed from the second side and extending over a part of the thickness of the metal layer, the first recess opening into the second recess;
an electronic module including:
a support having an internal side and an external side, which is opposite from the internal side,
an array of external contact pads disposed on the external side of the support and configured to allow contact-based communication with an external terminal,
a microcircuit carried by the support and electrically connected to the external contact, and
a first set of bonding pads disposed on the internal side of the support and electrically connected to the microcircuit,
the electronic module being received in the first recess with the array of external contact pads flush with the first side of the metal layer;
an electrical connection block including:
a substrate exhibiting an internal side and an external side, which is opposite from the internal side, and
a second set of bonding pads disposed on the internal side of the substrate,
the electrical connection block being received in the second recess with the second set of bonding pads electrically contact-connected with the first set of bonding pads of the electronic module;
a first radio-frequency antenna disposed outside the first recess and electrically connected to the second set of bonding pads of the electrical connection block; and
the first set of bonding pads of the electronic module and the second set of bonding pads of the electrical connection block electrically interconnecting the microcircuit and the first radio-frequency antenna.

2. A smart card according to claim 1, wherein the electrical connection block has a via, integrated in the substrate, for electrically connecting the second set of bonding pads and the first radio-frequency antenna.

3. The smart card according to claim 1, wherein the substrate of the electrical connection block carries the first radio-frequency antenna.

4. The smart card according to claim 1, further comprising an insulating layer, separate from the electrical connection block, and a second radio-frequency antenna, the insulating layer carrying the second radio-frequency antenna, the insulating layer and the second radio-frequency antenna being disposed opposite the second side of the metal layer, the second radio-frequency antenna being configured to allow magnetic coupling with the first radio-frequency antenna.

5. The smart card according to claim 4, further comprising an external magnetic screening layer disposed between the second side of the metal layer and the insulating layer, the external magnetic screening layer exhibiting a first through opening aligned with the second recess, the electrical connection block being received at least in part in the first through opening in the external magnetic screening layer.

6. The smart card according to claim 1, wherein the metal layer includes a first stop member configured to prevent the electrical connection block from moving towards the first recess and/or a second stop member configured to prevent the electronic module from moving towards the second recess.

7. The smart card according to claim 6, wherein the second stop member is formed by the electrical connection block disposed in the second recess.

8. The smart card according to claim 6, further comprising an internal magnetic screening layer disposed in the second recess, between the electrical connection block and the first stop member.

9. The smart card according to claim 1, wherein the first recess defines a first perimeter on the first side of the metal layer, while the second recess defines a second perimeter on the second side of the metal layer, the first perimeter delimiting a surface area that is less than a surface area delimited by the second perimeter.

10. A method for manufacturing a smart card including a card body having a metal layer, the metal layer having a first side, a second side opposite from the first side, and a thickness defined between the first side and the second side, the metal layer exhibiting a first recess formed from the first side and extending over a part of the thickness of the metal layer and a second recess formed from the second side and extending over a part of the thickness of the metal layer, the first recess opening into the second recess, an electronic module including: a support having an internal side and an external side, which is opposite from the internal side, an array of external contact pads disposed on the external side of the support and configured to allow contact-based communication with an external terminal, a microcircuit carried by the support and electrically connected to the external contact, and a first set of bonding pads disposed on the internal side of the support and electrically connected to the microcircuit, the electronic module being received in the first recess with the array of external contact pads flush with the first side of the metal layer, an electrical connection block including: a substrate exhibiting an internal side and an external side, which is opposite from the internal side, and a second set of bonding pads disposed on the internal side of the substrate, the electrical connection block being received in the second recess with the second set of bonding pads electrically contact-connected with the first set of bonding pads of the electronic module, a first radio-frequency antenna disposed outside the first recess and electrically connected to the second set of bonding pads of the electrical connection block, and the first set of bonding pads of the electronic module and the second set of bonding pads of the electrical connection block electrically interconnecting the microcircuit and the first radio-frequency antenna, comprising:
introducing the electrical connection block into the second recess from the second side of the metal layer; and
introducing the electronic module into the first recess from the first side of the metal layer,
wherein the electrical interconnection between the microcircuit and the first radio-frequency antenna is produced by introducing the electronic module and/or introducing the electrical connection block into their respective recesses until the first set of bonding pads and the second set of bonding pads come into contact.

11. The method according to claim 10, wherein, during the introducing the electrical connection block, the electrical connection block is introduced until the electrical connection block abuts against a first stop member configured to prevent the electrical connection block from moving towards the first recess,
wherein the step of introducing the electrical connection block is carried out before the introducing the electronic module, and
wherein, during the introducing the electronic module, the electronic module is introduced until the electrical block abuts against the electrical connection block.

12. The method according to claim 10, further comprising:
forming the first recess from the first side of the metal layer; and
forming the second recess from the second side of the metal layer,
wherein the forming the first recess and forming the second recess being are carried out before the introducing the electrical connection block and introducing the electronic module.

13. The smart card according to claim 2, wherein the substrate of the electrical connection block carries the first radio-frequency antenna.

14. The smart card according to claim 2, further comprising an insulating layer, separate from the electrical connection block, and a second radio-frequency antenna, the insulating layer carrying the second radio-frequency antenna, the insulating layer and the second radio-frequency antenna being disposed opposite the second side of the metal layer, the second radio-frequency antenna being configured to allow magnetic coupling with the first radio-frequency antenna.

15. The smart card according to claim 3, further comprising an insulating layer, separate from the electrical connection block, and a second radio-frequency antenna, the insulating layer carrying the second radio-frequency antenna, the insulating layer and the second radio-frequency antenna being disposed opposite the second side of the metal layer, the second radio-frequency antenna being configured to allow magnetic coupling with the first radio-frequency antenna.

16. The smart card according to claim 2, wherein the metal layer includes a first stop member configured to prevent the electrical connection block from moving towards the first recess and/or a second stop member configured to prevent the electronic module from moving towards the second recess.

17. The smart card according to claim 3, wherein the metal layer includes a first stop member configured to prevent the electrical connection block from moving towards the first recess and/or a second stop member configured to prevent the electronic module from moving towards the second recess.

18. The smart card according to claim 4, wherein the metal layer includes a first stop member configured to prevent the electrical connection block from moving towards the first recess and/or a second stop member configured to prevent the electronic module from moving towards the second recess.

19. The smart card according to claim 5, wherein the metal layer includes a first stop member configured to prevent the electrical connection block from moving towards the first recess and/or a second stop member configured to prevent the electronic module from moving towards the second recess.

20. The smart card according to claim 7, further comprising an internal magnetic screening layer disposed in the second recess, between the electrical connection block and the first stop member.
